(19) United States
(12) Patent Application Publication
(10) Pub. No.: US 2024/0327309 A1
(43) Pub. Date: Oct. 3, 2024

(54) METHOD FOR PRODUCING COATED SUBSTRATES, COATED SUBSTRATE, AND USE THEREOF

(71) Applicant: FRAUNHOFER-GESELLSCHAFT ZUR FÖRDERUNG DER ANGEWANDTEN FORSCHUNG E.V., München (DE)

(72) Inventors: Kevin SCHUCK, Erlangen (DE); Christian REIMANN, Erlangen (DE); Michael LANG, Erlangen (DE)

(73) Assignee: FRAUNHOFER-GESELLSCHAFT ZUR FÖRDERUNG DER ANGEWANDTEN FORSCHUNG E.V., München (DE)

(21) Appl. No.: 18/293,861

(22) PCT Filed: Aug. 1, 2022
(86) PCT No.: PCT/EP2022/071551

§ 371 Date: Jan. 31, 2024

(30) Foreign Application Priority Data
Aug. 3, 2021 (EP) 21189486.0

(51) Int. Cl. C04B 41/52; C04B 35/56; C04B 35/626; C04B 35/63; C04B 35/64; C04B 41/00; C04B 41/45; C04B 41/50; C04B 41/87; C04B 41/89; C23C 16/448; C30B 25/02; C30B 29/40

(52) U.S. Cl. CPC C04B 41/524; C04B 35/5607; C04B 35/6263; C04B 35/6303; C04B 35/64; C04B 41/0072; C04B 41/009; C04B 41/4539; C04B 41/5057; C04B 41/87; C04B 41/89; C23C 16/4485; C30B 25/02; C04B 2235/3839; C04B 2235/3891; C04B 2235/428; C04B 2235/5436; C04B 2235/6567; C04B 2235/95; C30B 29/406

(57) ABSTRACT

Disclosed is a method for producing coated substrates, wherein a first aqueous suspension and a second aqueous suspension are produced, a layer of the first aqueous suspension is applied onto a substrate, a layer of the second aqueous suspension is applied onto the layer of the first aqueous suspension applied onto the substrate, and the resulting substrate coated is sintered. The first and second aqueous suspensions each contains a refractory metal carbide, a sinter additive and water. Additionally, the second aqueous suspension can contain a sinter additive, wherein the content by weight percentage of the sinter additive in the second aqueous suspension, based on the total weight of the second aqueous suspension, is less than the content by weight percentage of the sinter additive in the first aqueous suspension, based on the total weight of the first aqueous suspension. Also disclosed are a coated substrate produced using the method and the use of the coated substrate.

The present invention relates to a method for preparing coated substrates, in which a first aqueous suspension and a second aqueous suspension are prepared, at least one layer of the first aqueous suspension is applied to a substrate, at least one layer of the second aqueous suspension is applied to the at least one layer of the first aqueous suspension applied to the substrate and the substrate coated in this way is subjected to a sintering process. The first aqueous suspension comprises or consists of at least one refractory metal carbide, at least one sintering additive is selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, and water. The second aqueous suspension also comprises at least one refractory metal carbide and water. In addition, the second aqueous suspension can comprise at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, the percentage by weight of the at least one sintering additive in the second aqueous suspension, based on the total weight of the second aqueous suspension, being less than the percentage by weight of the at least one sintering additive in the first aqueous suspension, based on the total weight of the first aqueous suspension. Alternatively, the second aqueous suspension can also comprise no sintering additive. The present invention further relates to a coated substrate which is prepared or can be prepared using the method according to the invention, and the use of such a coated substrate.

Refractory metal carbides such as tantalum carbide (TaC) are generally characterized by their high mechanical, chemical and thermal resistance. The use of said materials focuses primarily on high-temperature applications, for example, in semiconductor crystal growth, in which highly corrosive and aggressive species are present and the usability of the existing component (for example, made of graphite) is thus restricted or the service life thereof is significantly reduced. Since it is proving difficult to produce a proven volume component from refractory metal carbides at low cost and in complex geometry using the hot pressing processes described from the literature, coatings are preferably used. The preparation of ceramic layers via hot pressing is not possible due to the process. Coatings are prepared, for example, via the CVD process. Dense layers of a few micrometers are deposited on a substrate via the gas phase. An example thereof would be TaC coatings in a single-layer structure. However, this cost-intensive method prevents coated components with any geometries and sizes from being realized with an arbitrary layer thickness. To ensure greater flexibility in these areas, there is the option of applying the coatings to the substrate via a wet ceramic process (dipping, brushing or spraying). This can be achieved, for example, via a suspension based on organic solvents (see, for example, US 2013/0061800 A1). To produce the desired protective coating properties, a sintering process is added downstream of the application process via an initial suspension.

In addition to the generation of a mechanically stable coating by the final sintering process (high abrasion and adhesion resistance), a high degree of compaction is required at the same time in order to optimally protect the substrate from corrosive media in high-temperature applications. Since the refractory metal carbides are mainly compounds that have strong covalent bonds and very little self-diffusion, a first challenge is to optimize the sintering process for a maximum possible yield of the degree of compaction. A popular method for increasing the sintering activity, especially in the field of pressureless sintering, is the use of sintering aids, which turn into a liquid melt phase during the sintering process and thus lead to a preferred particle rearrangement (liquid phase sintering). It should preferably be ensured that the sintering aid forms a stable melt phase under the given sintering conditions (temperature, pressure, etc.). When using selected sintering additives, it can also be advantageous to adapt the sintering conditions for an ideal sintering result, for example, by increasing the system pressure with an inert gas atmosphere.

From work that has already been published (see for example, US 2013/0061800 A1), it is known that the use of certain transition metals as sintering additives, such as cobalt, can lead to a maximization of the degree of compaction in the pressureless sintering of TaC coatings. However, cobalt is a very toxic substance that poses environmental, health and safety problems for suspension-based coating technology. Furthermore, highly flammable powder mixtures are possible when using certain transition metals as sintering additives, which can also be questionable from a safety point of view. The use of a refractory metal carbide-based protective layer in semiconductor crystal growth also stipulates that critical impurities, including above all the transition metals cobalt, nickel, iron, etc. known from the literature, must under no circumstances get into the growth atmosphere from the internal structure of the reactor in which the coating is to be used.

Proceeding therefrom, it was the object of the present invention to specify a method for preparing coated substrates which is less critical from a safety point of view and which is particularly well suited for use in high-temperature applications, such as in semiconductor crystal growth. In addition, it was the object of the present invention to provide coated substrates that can be prepared in a safer manner from a safety point of view and are particularly well suited for use in high-temperature applications, such as in semiconductor crystal growth.

This object is achieved by means of the features of claim 1 with regard to a method for preparing coated substrates and by means of the features of claim 10 with regard to a coated substrate. Claim 15 specifies possible uses of the coated substrate according to the invention. The dependent claims represent advantageous developments.

According to the invention, a method for preparing coated substrates is thus specified, in which
a) a first aqueous suspension is prepared, which comprises or consists of at least one refractory metal carbide, at least one sintering additive selected from the group consisting of silicon, hafnium, zirconium, vanadium, tantalum pentoxide (Ta₂O₅), boron carbide (B₄C), silicon carbide, tungsten carbide, vanadium carbide, molybdenum carbide, boron nitride, tantalum nitride, zirconium nitride, niobium nitride, tantalum diboride, tungsten diboride, zirconium boride (or zirconium diboride, ZrB₂), refractory metal silicides and mixtures thereof, and water,
b) a second aqueous suspension is prepared, which comprises at least one refractory metal carbide and water, the second aqueous suspension comprising
   at least one sintering additive selected from the group consisting of silicon, hafnium, zirconium, vanadium, tantalum pentoxide (Ta₂O₅), boron carbide (B₄C), silicon carbide, tungsten carbide, vanadium carbide, molybdenum carbide, boron nitride, tantalum nitride, zirconium nitride, niobium nitride, tantalum diboride, tungsten diboride, zirconium boride (or zirconium diboride, ZrB₂), refractory metal silicides and mixtures thereof, the percentage by weight of the at least one sintering additive in the second aqueous suspension, based on the total weight of the second aqueous suspension, being smaller than the percentage by weight of the at least one sintering additive in the first aqueous suspension, based on the total weight of the first aqueous suspension, or
   comprising no sintering additive,
c) at least one layer of the first aqueous suspension is applied to a substrate,
d) at least one layer of the second aqueous suspension is applied to the at least one layer of the first aqueous suspension applied to the substrate, and
e) the (coated) substrate is subjected to a sintering process after step d).

A first aqueous suspension is prepared in step a) of the method according to the invention and a second aqueous suspension is prepared in step b) of the method according to the invention. step b) can be carried out before step a), after step a) or (at least partially) simultaneously with step a). The first aqueous suspension and/or the second aqueous suspension can (respectively) be prepared by mixing the components to be comprised in the respective suspension. The first aqueous suspension and the second aqueous suspension each comprise at least one refractory metal carbide and water. The at least one refractory metal carbide comprised in the first aqueous suspension and the at least one refractory metal carbide comprised in the second aqueous suspension can be the same refractory metal carbide or different refractory metal carbides. In addition, the first aqueous suspension comprises at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof. The second aqueous suspension can also comprise a sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, wherein the percentage by weight of the at least one sintering additive in the second aqueous suspension, based on the total weight of the second aqueous suspension, is then less than the percentage by weight of the at least one sintering additive in the first aqueous suspension, based on the total weight of the first aqueous suspension. Alternatively, the second aqueous suspension can also comprise no sintering additive. For example, the second aqueous suspension may comprise no sintering additive selected from the group consisting of silicon; tantalum pentoxide; silicon carbide; tungsten carbide; vanadium carbide; molybdenum carbide; boron nitride; tantalum nitride; zirconium nitride; niobium nitride; tantalum diboride; tungsten diboride; zirconium boride; refractory metal silicides, for example, TaSi₂, MoSi₂, ZrSi₂; transition metals, for example, hafnium, zirconium, vanadium; boron carbide (B₄C); silicon nitride (Si₃N₄); carbon; and mixtures thereof. Preferably, the second aqueous suspension consists of at least one refractory metal carbide, water, and optionally at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof. The at least one sintering additive comprised in the first aqueous suspension and the at least one sintering additive comprised in the second aqueous suspension can be the same sintering additive or different sintering additives.

The at least one sintering additive comprised in the first aqueous suspension is preferably selected from the group consisting of silicon, zirconium boride, refractory metal silicides and mixtures thereof.

If the second aqueous suspension comprises at least one sintering additive, then said at least one sintering additive comprised in the second aqueous suspension is preferably selected from the group consisting of silicon, zirconium boride, refractory metal silicides and mixtures thereof.

For example, the second aqueous suspension consists of at least one refractory metal carbide, water, and optionally at least one sintering additive selected from the group consisting of silicon, zirconium boride, refractory metal silicides and mixtures thereof.

It is possible for the second aqueous suspension to comprise no sintering additive. For example, the second aqueous suspension may comprise no sintering additive selected from the group consisting of silicon; zirconium boride; refractory metal silicides, for example, TaSi₂, MoSi₂, ZrSi₂; transition metals; boron carbide (B₄C); silicon nitride (Si₃N₄); carbon; and mixtures thereof.

A sintering additive can be understood as a substance that is added specifically as an aid for the sintering of ceramic systems for the preparation of ceramic components in order to control the microstructural and spatial development (for example, shrinkage, grain growth, shape change and/or homogenization).

At least one layer of the first aqueous suspension is applied to a substrate in step c) of the method according to the invention. The substrate can preferably be a carbon substrate, particularly preferably a graphite substrate, very particularly preferably an iso-graphite substrate. Isographite is understood to mean graphite that was prepared by the isostatic pressing process. For example, the substrate can be a crucible, preferably a carbon crucible, particularly preferably a graphite crucible, very particularly preferably an iso-graphite crucible. The at least one layer of the first aqueous suspension can be applied to the substrate, for example, by means of dipping, brushing, spray application or a combination thereof. For example, at least one layer of the first aqueous suspension with an average layer thickness of at least 20 μm, preferably from 20 μm to 150 μm, particularly preferably from 30 μm to 100 μm, can be applied to the substrate.

In step d) of the method according to the invention, at least one layer of the second aqueous suspension is applied to the at least one layer of the first aqueous suspension applied to the substrate in step c). The at least one layer of the second aqueous suspension can be applied, for example, by dipping, brushing, spray application or a combination thereof. For example, at least one layer of the second aqueous suspension with an average layer thickness of at least 20 μm, preferably from 20 μm to 150 μm, particularly preferably from 30 μm to 100 μm, can be applied to the at least one layer of the first aqueous suspension applied to the substrate in step c).

The substrate is subjected to a sintering process in step e) of the method according to the invention. This is carried out after step d), that is, after the application of the at least one layer of the second aqueous suspension to the at least one layer of the first aqueous suspension applied to the substrate. The coated substrate subjected to the sintering process in step e) thus has both the at least one layer of the first aqueous suspension applied in step c) and the at least one layer of the second aqueous suspension applied in step d). Thus, in step e), both the at least one layer of the first aqueous suspension and the at least one layer of the second aqueous suspension are simultaneously subjected to a sintering process. At least one first sintered layer comprising at least one refractory metal carbide from the at least one layer of the first aqueous suspension and also at least one second sintered layer comprising at least one refractory metal carbide from the at least one layer of the second aqueous suspension can be prepared by the sintering process.

The method according to the invention enables the preparation of refractory metal carbide-based layers on substrates, which can serve as high-temperature and wear-protection layers or wear-protection layer systems.

The method according to the invention is a wet-ceramic method for preparing refractory metal carbide-based coatings on substrates. In contrast to layers prepared via CVD or PVD processes, the layers prepared via wet ceramic processes show an isotropic texture with random grain size orientation, which leads to a reduced susceptibility to cracking and an increase in the diffusion path for substrate-damaging species. Because of this, the coated substrates prepared according to the invention have improved protection against aggressive substances used in high-temperature applications compared to coated substrates prepared via CVD or PVD methods. In addition, the wet ceramic method according to the invention is more cost-effective than CVD or PVD methods and also offers more flexibility in terms of the geometries and sizes of the coated components that can be prepared and the layer thicknesses of the coatings or layers applied.

Furthermore, the method according to the invention for preparing coated substrates is based on the use of an aqueous suspension. The use of aqueous suspensions has various advantages over the use of organic suspensions. In contrast to organic suspensions, aqueous suspensions are inexpensive, harmless from an ecological and health point of view and do not involve the safety-related problem of easily flammable spray mist. In addition, when using aqueous suspensions, there is no need for pyrolysis to remove organic solvents, which can lead to the undesired entry of foreign substances into the coating. Furthermore, a controlled application of the suspension is possible when using aqueous suspensions, in contrast to using the known organic suspensions. Controlled application is not possible, particularly with the spray application of the known organic suspensions, since the suspension properties can fluctuate during said process due to evaporation of the solvent, so that homogeneous layers cannot be obtained over time.

One or more sintering additives are used In the method according to the invention, the sintering additives being selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, preferably selected from the group consisting of silicon, zirconium boride, refractory metal silicides and mixtures thereof. It has been shown that said sintering additives used according to the invention, due to their properties (for example, melting points, boiling points, etc.), have at least the same or even a better effect on the degree of compaction than the transition metals (for example, cobalt, nickel, iron, etc.) used in the prior art as sintering additives. A high degree of compaction of the sintered layer prepared on the substrate can thus be achieved by using said additives, by which the substrate is very well protected from corrosive media in high-temperature applications. Compared to the sintering additives used in the prior art, such as cobalt, the sintering additives used according to the invention are initially distinguished by the fact that they are harmless in terms of safety and health. In addition, using sintering additives according to the invention and thus avoiding certain transition metals, such as cobalt, nickel, iron, as sintering additives, prevents said transition metals from remaining as impurities in the layer, which would be harmful to the growth atmosphere there if the coated substrate were used in high-temperature applications in semiconductor crystal growth.

Because the second aqueous suspension either comprises no sintering additive or comprises a lower percentage by weight of sintering additive than is comprised in the first aqueous suspension, the coating prepared on the substrate using the method according to the invention has a very advantageous layer structure of at least two different sintered layers. Said layer structure comprises at least one first sintered layer arranged on the substrate, the first sintered layer comprising or consisting of at least one refractory metal carbide and at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, and at least one second sintered layer arranged on the at least one first sintered layer, the second sintered layer comprising or consisting of at least one refractory metal carbide and optionally at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof. The at least one sintering additive can also be present at least partially in decomposed form and/or in the form of a reaction product of a reaction of the at least one sintering additive with the at least one refractory metal carbide. Since the presence of a sintering additive or a higher proportion of a sintering additive in the layer obtained during the sintering process leads to a higher degree of compaction of the sintered layer, after the sintering process, the second sintered layer of the layer structure has a lower relative density or a lower degree of compaction than that first sintered layer. The layer structure obtained thus has a density gradient in which the degree of compaction or the relative density decreases with increasing distance from the substrate (that is, from the first sintered layer to the second sintered layer). For example, the at least one first sintered layer can have a relative density of at least 70% and the relative density of the at least one second sintered layer can be at least 3% lower than the relative density of the at least one first sintered layer.

Due to the higher proportion of sintering additive in the first aqueous suspension, the first sintered layer of the coated substrate prepared (that is, the first layer of the layer structure that is in direct contact with the substrate) has a comparatively high degree of compaction or a comparatively high relative density, which is why the substrate is very well protected against aggressive media in high-temperature applications. Since the second aqueous suspension comprises a lower proportion of sintering additive or comprises no sintering additive, the second sintered layer of the coated substrate prepared (that is, the second layer of the layer structure) also comprises no or only comprises a small amount of sintering additive, which can reduce the risk that when the coated substrate prepared is used in high-temperature applications in semiconductor crystal growth, sintering additive from the coating can enter the growth atmosphere and contaminate said atmosphere. In this case, the at least one second sintered layer can also act as a protective layer, which reduces the risk of sintering additive from the at least one first sintered layer getting into the growth atmosphere. In addition, the at least one second sintered layer has a lower degree of compaction or a lower relative density than the at least one first sintered layer due to the lower proportion of sintering additive or because of the lack of the sintering additive in the second aqueous suspension. The higher porosity of the at least one second sintered layer resulting therefrom leads to advantages when using the coated substrate in high-temperature applications in semiconductor crystal growth, since a larger contact surface for the melt used in crystal growth is obtained through said higher porosity, the evaporation rate and thus also the growth rate thereby being able to be increased.

As a result of the layer system just described obtained using the method according to the invention, the coated substrate prepared according to the invention is consequently particularly well suited for use in high-temperature applications, such as in semiconductor crystal growth.

By choosing the amount of sintering additive in the first and second aqueous suspension and optionally also adjusting the sintering parameters, the relative density in the individual layers of the layer system can be set such that a desired density gradient can be achieved within the layer system. It is particularly advantageous here if the layer system has a low density gradient, since the layer system is then thermally even more stable.

The coated substrate that can be prepared using the method according to the invention can be used, for example, as a gallium evaporator or part of a gallium evaporator in a VPE-GaN reactor that can be used to grow gallium nitride semiconductor crystals, the layer system obtained in the method according to the invention then functioning as a coating for the gallium evaporator. In this case, the base material of the gallium evaporator can be protected particularly well from the corrosive gallium melt by the at least one first sintered layer of the layer system (that is, the sintered layer resulting from the first aqueous suspension) due to the higher relative density, whereas due to the lower relative density and the higher porosity of the at least one second sintered layer of the layer system (that is, the sintered layer resulting from the second aqueous suspension), the gallium evaporation rate and thus also the gallium nitride growth rate can be increased, since there is a larger contact area for the gallium melt.

The at least one coated substrate is preferably not subjected to a sintering process between steps c) and d). This means that the substrate coated with the at least one layer of the first aqueous suspension is preferably not subjected to a sintering process before the at least one layer of the second aqueous suspension has been applied to the at least one layer of the first aqueous suspension applied to the substrate. Because the coated substrate is only subjected to a sintering process after step d), the at least one layer of the first aqueous suspension applied in step c) and the at least one layer of the second aqueous suspension applied in step d) can be sintered simultaneously in a sintering process. A separate sintering of each of the two layers after the respective application of the layer is thereby avoided, a sintering step thereby being dispensed with. As a result, the process is faster and cheaper. In addition, when the at least one layer of the second aqueous suspension is applied to an already sintered layer of the first aqueous suspension, the connection can be weakened due to a lack of infiltration and delamination can thus occur more easily in the event of thermal stresses. This can be avoided by jointly sintering the two layers applied in steps c) and d) in a sintering process after step d).

In step c) of the method according to the invention, the at least one layer of the first aqueous suspension can be applied to the entire surface of the substrate or only to one or more sections of the surface of the substrate. In step d) of the method according to the invention, the at least one layer of the second aqueous suspension can be applied to the entire at least one layer of the first aqueous suspension applied in step c) or only on one or more sections of the at least one layer of the first aqueous suspension applied in step c). If the substrate is a crucible, for example, in step c), the at least one layer of the first aqueous suspension can be applied to the entire surface of the crucible and in step d), the at least one layer of the second aqueous suspension can be applied only to the section of the at least one layer of the first aqueous suspension located on the inner side(s) of the crucible.

A preferred variant of the method according to the invention is characterized in that
the substrate comprises or consists of a material selected from the group consisting of graphite, preferably iso-graphite, carbon fiber reinforced carbon (CFC), C/SiC fiber composites, SiC/SiC fiber composites, carbidic ceramics, nitridic ceramics, oxidic ceramics, and mixtures thereof, and/or
the refractory metal silicides (in step a) and/or in step b)) are selected from the group consisting of titanium silicides, zirconium silicides, for example, zirconium disilicide (ZrSi₂), hafnium silicides, for example, hafnium disilicide (HfSi₂), vanadium silicides, for example, vanadium disilicide (VSi₂), niobium silicides, for example, niobium disilicide (NbSi₂), tantalum silicides, for example, tantalum disilicide (TaSi₂), chromium silicides, molybdenum silicides, for example, molybdenum disilicide (MoSi₂), tungsten silicides, for example, tungsten disilicide (WSi₂), and mixtures thereof, and/or
the at least one refractory metal carbide (in step a) and/or in step b)) is selected from the group consisting of titanium carbides, zirconium carbides, hafnium carbides, vanadium carbides, niobium carbides, tantalum carbides, chromium carbides, molybdenum carbides, tungsten carbides, and mixtures thereof.

According to a particularly preferred variant of the method according to the invention, the refractory metal silicides (in step a) and/or in step b)) are selected from the group consisting of zirconium disilicide (ZrSi₂), hafnium disilicide (HfSi₂), vanadium disilicide (VSi₂), niobium disilicide (NbSi₂), tantalum disilicide (TaSi₂), molybdenum disilicide (MoSi₂), tungsten disilicide (WSi₂), and mixtures thereof.

Due to the ecological, health and safety-related harmless use, combined with a melting temperature range between 1400° C. and 2200° C., the refractory metal silicides selected from the group consisting of titanium silicides, zirconium silicides, hafnium silicides, vanadium silicides, niobium silicides, tantalum silicides, chromium silicides, molybdenum silicides, tungsten silicides, and mixtures thereof are optimally suited as sintering additives for the high-temperature sintering process. By using said metal silicides as a sintering additive, the desired melt phase can be formed during the heating-up phase and a favorable rearrangement of the particles to increase the sintering activity can take place before active sintering. The melting temperature of the sintering additive can therefore be lower than the sintering temperature. In addition, the boiling temperature of the sintering additive under the given pressure conditions can be significantly higher than the sintering temperature used, thereby ensuring a certain stability of the liquid phase over the entire sintering process and avoiding possible evaporation. In addition, the melting temperature of the sintering additives can be below the application temperature of the refractory metal carbide coating (for example, TaC coating), thereby preventing the sintering additive from evaporating during use.

It is particularly advantageous if the at least one sintering additive is MoSi₂, TaSi₂ or mixtures thereof. Having a melting point of approx. 2050° C., said sintering additives have high temperature stability and are thus particularly suitable for use at high temperatures, for example, in reactor interior structures.

The at least one refractory metal carbide is very particularly preferably tantalum carbide. Tantalum carbide enables a particularly good protective effect for the substrate.

The substrate can preferably comprise or consist of a material that is selected from the group consisting of graphite, preferably iso-graphite, carbide ceramics, nitride ceramics, oxidic ceramics, and mixtures thereof.

The substrate can preferably comprise or consist of a material selected from the group consisting of graphite, preferably iso-graphite, carbon fiber reinforced carbon (CFC), C/SiC fiber composites, SiC/SiC fiber composites, and mixtures thereof.

Carbon-based substrates and SiC-based substrates show increased infiltration behavior when an aqueous suspension is applied. As a result, the method according to the invention is particularly suitable for such substrates.

The substrate very particularly preferably comprises or consists of graphite, preferably iso-graphite.

A further preferred variant of the method according to the invention is characterized in that the at least one refractory metal carbide and the at least one sintering additive are each present in particulate form, the mean particle size of the particles of the at least one sintering additive being less than 5 μm and/or smaller than the mean particle size of the particles of the at least one refractory metal carbide. A particle size of the particles of the at least one sintering additive of less than 5 μm makes it possible to avoid larger holes or even a loss of structure in the coating after the sintering process. An average particle size of the particles of the at least one sintering additive that is smaller than the average particle size of the particles of the at least one refractory metal carbide leads to the advantage that the sintering additive particles can accumulate better in the gaps in the refractory metal carbide layer. The mean particle size of the particles of the at least one refractory metal carbide can preferably be in the range between 0.2 and 2 μm.

The mean particle size of the particles of the at least one refractory metal carbide and/or the mean particle size of the particles of the at least one sintering additive can be determined, for example, by means of laser diffraction (DIN 13320:2020-01).

According to a further preferred variant of the method according to the invention, the at least one refractory metal carbide is present as a powder mixture which comprises or consists of powders which differ in the mean particle size of the particles, preferably of the same refractory metal carbide. In other words, a powder mixture is used here as the at least one refractory metal carbide, the powder mixture comprising different refractory metal carbide particles, preferably of the same refractory metal carbide, said particles differing from one another in terms of their average particle size. For example, the powder mixture can comprise two types of particles, preferably of the same refractory metal carbide, the average particle diameter of the particles of the first type being larger than the average particle diameter of the particles of the second type. For example, different powders of the same refractory metal carbide can be mixed together in specific ratios of nano- and micron-sized particles to obtain such a powder mixture. Because the at least one refractory metal carbide is present as a powder mixture, the arrangement of the refractory metal carbide powder particles on the substrate can be designed to be more gap-free, since open spaces can be filled better. In this way, the relative density of the layer prepared can be increased independently of the presence and amount of a sintering additive in the layer.

The at least one refractory metal carbide is preferably present in the preparation of the second aqueous suspension in step b) as a powder mixture that comprises or consists of powders of the same refractory metal carbide that differ in the mean particle size of the particles, the second aqueous suspension preferably comprising no sintering additive. In this way, the relative density of the layer resulting from the at least one second suspension can be increased (preferably without using a sintering additive), resulting in a lower density gradient in the layered structure, the thermal stability of the layered structure and the quasi-diffusion-inhibiting effect thereby being increased (for example, with respect to the diffusion of impurities into a growth atmosphere). Because of a lower density difference, an abrupt change in the layer densities and the unevenly distributed thermal stresses in the layer system resulting therefrom can be avoided, which can lead to cracks, delamination or, in the worst case, failure of the layer system. The layer system is consequently more thermally stable. In addition, due to the use of refractory metal carbide particles of different particle sizes, the second layer also has a comparatively low porosity, so that said layer can act as a separating layer to the outer atmosphere, resulting in a quasi-diffusion-inhibiting effect.

A further preferred variant of the method according to the invention is characterized in that the first aqueous suspension and/or the second aqueous suspension
comprises 60 to 90% by weight, preferably 70 to 85% by weight, of the at least one refractory metal carbide, based on the total weight of the respective aqueous suspension, and/or
comprises 0.1 to 20% by weight, preferably 0.5 to 10% by weight, of the at least one sintering additive, based on the total weight of the respective aqueous suspension.

For example, the first aqueous suspension can comprise 0.2 to 20.0% by weight, preferably 0.6 to 10.0% by weight, of the at least one sintering additive, based on the total weight of the respective aqueous suspension, and/or the second aqueous suspension can comprise 0.1 to 19.9% by weight, preferably 0.5 to 9.9% by weight, of the at least one sintering additive, based on the total weight of the respective aqueous suspension.

According to a further preferred variant of the method according to the invention, the percentage by weight of the at least one sintering additive in the second aqueous suspension, based on the total weight of the second aqueous suspension, is around 0.1% by weight to 20% by weight, preferably around 0.5% to 10% by weight less than the weight percentage of the at least one sintering additive in the first aqueous suspension, based on the total weight of the first aqueous suspension. A low density gradient within the layer structure of the first layer (that is, the layer resulting from the first aqueous suspension) and the second layer (that is, the layer resulting from the second aqueous suspension) can be obtained in this way, the thermal stability of the layer structure and the quasi-diffusion-inhibiting effect (for example, with regard to the diffusion of impurities into a growth atmosphere) thereby being increased. Because of a lower density difference, an abrupt change in the layer densities and the unevenly distributed thermal stresses in the layer system resulting therefrom can be avoided, which can lead to cracks, delamination or, in the worst case, failure of the layer system. The layer system is consequently more thermally stable. In addition, due to the use of the sintering additive, the second layer also has a comparatively low porosity, so that said layer can act as a separating layer to the external atmosphere, resulting in a quasi-diffusion-inhibiting effect.

For example, the percentage by weight of the at least one sintering additive in the second aqueous suspension, based on the total weight of the second aqueous suspension, can be smaller by 0.1% by weight to 19.9% by weight, preferably by 0.5% by weight to 9.9% by weight than the percentage by weight of the at least one sintering additive in the first aqueous suspension, based on the total weight of the first aqueous suspension.

The at least one first aqueous suspension and/or the at least one second aqueous suspension can comprise at least one binder selected from the group consisting of polyvinyl alcohols, polyethylene glycol, polyvinyl butyral, polyacrylic acid, polyurethanes, chloroprene rubber, phenolic resins, acrylic resins, carboxymethyl cellulose, alginic acid, dextrins, sodium biphenyl-2-yl oxides, polyphenyl oxide, and mixtures thereof, preferably selected from the group consisting of polyvinyl alcohols, sodium biphenyl-2-yl oxides, polyphenyl oxide, and mixtures thereof, the at least one binder preferably being able to be present in a proportion of 0.05 to 1% by weight or from 0.01 to 5% by weight, based on the total weight of the respective aqueous suspension, in the at least one first aqueous suspension and/or the at least one second aqueous suspension.

A further preferred variant of the method according to the invention is characterized in that the preparation of the first aqueous suspension in step a) and/or the preparation of the second aqueous suspension in step b) is carried out by mixing the components of the suspension to be prepared with the aid of a dispersing device, the mixing taking place with the aid of the dispersing device, preferably using grinding media and/or over a period of at least 12 hours. Optimal mixing of the respective aqueous suspension can be achieved in this way, so that inhomogeneities in the distribution of the sintering additive and thus in compaction can be avoided. For example, rotational speeds of up to 1 m/s can be used when mixing with the dispersing device.

A further preferred variant of the method according to the invention is characterized in that the application of the at least one layer of the first aqueous suspension in step c) and/or the application of the at least one layer of the second aqueous suspension in step d)
is carried out by means of dipping, brushing or spray application, and/or
is carried out with an average layer thickness of less than 150 μm, preferably from 20 μm to 100 μm, particularly preferably from 30 am to 80 μm.

Spray application is the preferred choice for the preparation of one or more thin, fast drying refractory metal carbide layers, preferably with layer thicknesses in the range of 20 μm to 80 μm. A very thin suspension layer can be applied to the surface by a rapid rotation of the component using the spray jet, which can dry quickly to very quickly, depending on the solids content of the suspension. Solids contents of the refractory metal carbide powder are preferably greater than or equal to 70% by weight of the total suspension. Each individual layer to be applied should preferably show a comparable drying behavior. In principle, quick-drying behavior of the applied suspension layers is preferred, since differences in density between refractory metal carbide and sintering additive can lead to inhomogeneity in the distribution of the particles if the layers dry for too long.

A further preferred variant of the method according to the invention is characterized in that at least one third aqueous suspension is additionally prepared, the third aqueous suspension comprising or consisting of at least one refractory metal carbide and water, the at least one third aqueous suspension comprising no sintering additive, and between steps d) and e), at least one layer of the at least one third aqueous suspension being applied to the at least one applied layer of the second aqueous suspension. The at least one layer of the first aqueous suspension, the at least one layer of the second aqueous suspension and the at least one layer of the third aqueous suspension can then be sintered together (simultaneously) in the sintering process step e). This creates stable connections between the layers, which are also stable under thermal stress. The at least one refractory metal carbide comprised in the at least one third aqueous suspension can be identical to the refractory metal carbide comprised in the first aqueous suspension and/or to the refractory metal carbide comprised in the second aqueous suspension. The at least one refractory metal carbide comprised in the at least one third aqueous suspension is preferably selected from the group consisting of titanium carbides, zirconium carbides, hafnium carbides, vanadium carbides, niobium carbides, tantalum carbides, chromium carbides, molybdenum carbides, tungsten carbides, and mixtures thereof.

Preferably, a plurality of third aqueous suspensions can additionally be prepared, the third aqueous suspensions comprising or consisting of at least one refractory metal carbide and water, the plurality of third aqueous suspensions comprising no sintering additive, and between step d) and e), at least one layer of each of the third aqueous suspensions being applied one above the other to the at least one applied layer of the second aqueous suspension, so that a layer sequence results from the layers of the third aqueous suspension. In this way, the coated substrate obtained after the sintering can comprise a layer sequence of a plurality of third sintered layers, the relative density of the plurality of sintered layers within said layer sequence decreasing as the distance from the at least one second sintered layer increases. For example, the relative density in the individual layers of the layer sequence can be set such that a (desired) density gradient within the layer sequence can be achieved by adjusting the sintering parameters.

A further preferred variant of the method according to the invention is characterized in that the sintering process is carried out in step d)
is carried out at a temperature of from 2100° C. to 2500° C., preferably from 2200° C. to 2400° C., and/or
is carried out with a holding time of 1 h to 15 h, preferably of 2 h to 10 h, and/or
is carried out at a pressure of 0.1 bar to 10 bar, preferably 0.7 bar to 5 bar, and/or
is carried out such that after a first time segment of the sintering process, the pressure is increased, preferably by 3 bar to 7 bar, and/or
is carried out under an argon atmosphere.

These embodiments of the sintering process make it possible, on the one hand, to obtain a particularly advantageous ratio between the degree of compaction in the first layer of the layer structure (that is, the layer resulting from the first aqueous suspension) and the degree of compaction in the second layer of the layer structure (that is, the layer resulting from the second aqueous suspension). In addition, these embodiments of the sintering process increase the stability of the melt phase over the entire sintering process.

The preferred variant in which the pressure is increased after a first time segment of the sintering process in step e), preferably by 3 bar to 7 bar, can prevent the sintering additive from evaporating, for example, at a sintering temperature of 2300° C., the stable liquid phase simultaneously being optimally distributed between the particles.

According to a further preferred variant of the method according to the invention, the substrate is a graphite substrate, preferably an iso-graphite substrate.

The present invention further relates to a coated substrate, comprising a substrate, at least one first sintered layer arranged on the substrate, the first sintered layer comprising or consisting of at least one refractory metal carbide and at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, and at least one second sintered layer arranged on the at least one first layer, the second sintered layer comprising or consisting of at least one refractory metal carbide and optionally at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, the at least one first layer with a relative density of at least 70%, and the relative density of the at least one second layer being at least 3% lower than the relative density of the at least one first layer.

The presence of the at least one sintering additive in the first sintered layer and/or in the second sintered layer can be detected, for example, via an elementary analysis method or XRD analysis.

The relative density can be determined, for example, via REM cross-section analysis.

The at least one sintering additive can also be present in the first sintered layer and/or in the second sintered layer at least partially in decomposed form and/or in the form of a reaction product of a reaction of the at least one sintering additive with the at least one refractory metal carbide.

The at least one refractory metal carbide comprised in the first sintered layer and the at least one refractory metal carbide comprised in the second sintered layer may be the same refractory metal carbide or different refractory metal carbides. The second sintered layer may comprise a sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides, and mixtures thereof, the percentage by weight of the at least one sintering additive in the second sintered layer, based on the total weight of the second sintered layer, then being preferably smaller than the percentage by weight of the at least one sintering additive in the first sintered layer, based on the total weight of the first sintered layer. The at least one sintering additive comprised in the first sintered layer and the at least one sintering additive comprised in the second sintered layer can be the same sintering additive or different sintering additives. Alternatively, the second sintered layer can also comprise no sintering additive.

The at least one sintering additive comprised in the first sintered layer is preferably selected from the group consisting of silicon, zirconium boride, refractory metal silicides and mixtures thereof.

If the second sintered layer comprises at least one sintering additive, then said at least one sintering additive comprised in the second sintered layer is preferably selected from the group consisting of silicon, zirconium boride, refractory metal silicides and mixtures thereof.

The coated substrate according to the invention has a very advantageous layer structure made up of at least two different sintered layers. Due to the relative density of the at least one first sintered layer of at least 70%, the substrate is very well protected against aggressive or corrosive substances in high-temperature applications, such as the melt during semiconductor crystal growth. The at least one second sintered layer has a relative density that is at least 3% lower or a lower degree of compaction than the at least one first sintered layer. The layer structure obtained thus has a density gradient in which the degree of compaction or the relative density decreases with increasing distance from the substrate, that is, from the at least one first sintered layer to the at least one second sintered layer.

The higher porosity of the at least one second sintered layer resulting therefrom compared to the at least one first sintered layer leads to advantages when using the coated substrate in high-temperature applications in semiconductor crystal growth, since a larger contact surface for the melt used in crystal growth is obtained through said higher porosity, whereby the evaporation rate and thus the growth rate can be increased.

As a result of said advantageous layer system, the coated substrate according to the invention is therefore particularly well suited for use in high-temperature applications, such as in semiconductor crystal growth.

A preferred embodiment of the coated substrate according to the invention is characterized in that
the substrate comprises or consists of a material selected from the group consisting of graphite, preferably iso-graphite, carbon fiber reinforced carbon (CFC), C/SiC fiber composites, SiC/SiC fiber composites, carbidic ceramics, nitridic ceramics, oxidic ceramics, and mixtures thereof, and/or
the refractory metal silicides (in the first sintered layer and/or in the second sintered layer) are selected from the group consisting of titanium silicides, zirconium silicides, for example, zirconium disilicide (ZrSi₂), hafnium silicides, for example, hafnium disilicide (HfSi₂), vanadium silicides, for example, vanadium disilicide (VSi₂), niobium silicides, for example, niobium disilicide (NbSi₂), tantalum silicides, for example, tantalum disilicide (TaSi₂), chromium silicides, molybdenum silicides, for example, molybdenum disilicide (MoSi₂), tungsten silicides, for example, tungsten disilicide (WSi₂), and mixtures thereof, and/or
the at least one refractory metal carbide (in the first sintered layer and/or in the second sintered layer) is selected from the group consisting of titanium carbides, zirconium carbides, hafnium carbides, vanadium carbides, niobium carbides, tantalum carbides, chromium carbides, molybdenum carbides, tungsten carbides, and mixtures thereof.

According to a particularly preferred embodiment of the coated substrate according to the invention, the refractory metal silicides (in the first sintered layer and/or in the second sintered layer) are selected from the group consisting of zirconium disilicide (ZrSi₂), hafnium disilicide (HfSi₂), vanadium disilicide (VSi₂), niobium disilicide (NbSi₂), tantalum disilicide (TaSi₂), molybdenum disilicide (MoSi₂), tungsten disilicide (WSi₂), and mixtures thereof.

The at least one refractory metal carbide is very particularly preferably tantalum carbide.

The substrate can preferably comprise or consist of a material that is selected from the group consisting of graphite, preferably iso-graphite, carbide ceramics, nitride ceramics, oxidic ceramics, and mixtures thereof.

The substrate can preferably comprise or consist of a material selected from the group consisting of graphite, preferably iso-graphite, carbon fiber reinforced carbon (CFC), C/SiC fiber composites, SiC/SiC fiber composites, and mixtures thereof.

The substrate very particularly preferably comprises or consists of graphite, preferably iso-graphite.

The substrate can preferably be a carbon substrate, particularly preferably a graphite substrate, very particularly preferably an iso-graphite substrate. Isographite is understood to mean graphite that was prepared by the isostatic pressing process. For example, the substrate can be a crucible, preferably a carbon crucible, particularly preferably a graphite crucible, very particularly preferably an iso-graphite crucible.

Furthermore, it is preferred that the at least one first sintered layer and the at least one second sintered layer essentially comprises no cobalt, no nickel and no iron. “Essentially no cobalt, no nickel and no iron” is understood here to mean that the at least one first sintered layer and the at least one second sintered layer may comprise minimal amounts of cobalt, nickel and/or iron which do not interfere with the use of the coated substrate, for example, in semiconductor crystal growth. The formulation that the at least one first sintered layer and the at least one second sintered layer essentially comprise no cobalt, no nickel and no iron is preferably understood to mean that the at least one first sintered layer and the at least one second sintered layer comprise no more than 1% by weight, more preferably no more than 0.1% by weight, cobalt, no more than 1% by weight, more preferably no more than 0.1% by weight, nickel and no more than 1% by weight, particularly preferably no more than 0.1% by weight, iron, based on the total weight of the at least one first sintered layer and the at least one second sintered layer. The at least one first sintered layer and the at least one second sintered layer particularly preferably comprises no cobalt, no nickel and no iron.

By using one or more sintering additives selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides and mixtures thereof, the use of cobalt, nickel and iron as sintering additives can be dispensed with. As a result, the at least one first sintered layer and the at least one second sintered layer preferably comprises (essentially) no cobalt, no nickel and no iron. As a result, cobalt, nickel and iron cannot escape from the coated substrate as an impurity in an application, for example, in high-temperature application in semiconductor crystal growth, and negatively affect the application.

Furthermore, it is preferred that the grains, starting from the grain size of the initial sprayed layer or the sprayed-on particles, grow by at least a factor of 1.5, preferably a factor in a range from 1.5 to 10, particularly preferably a factor in a range from 1, 5 to 5.

A further preferred embodiment of the coated substrate according to the invention is characterized in that the at least one first sintered layer
has a relative density of more than 75%, preferably more than 80%, particularly preferably more than 90%, very particularly preferably more than 95%, and/or
has a permeability of less than 1 e⁻¹¹ m², preferably less than 1 e⁻¹³ m², and/or
has an adhesive strength of at least 2 MPa, preferably at least 4 MPa, and/or
has an average layer thickness of at least 20 μm, preferably from 20 μm to 150 μm, particularly preferably from 30 μm to 100 μm.

Furthermore, it is preferred that the at least one second sintered layer
has a relative density which is at least 5%, preferably at least 10%, particularly preferably 10% to 30%, very particularly preferably 15% to 25%, particularly 18% to 22% lower than the relative density of the at least one first sintered layer, and/or
has a permeability of less than 1 e⁻¹¹ m², preferably less than 1 e⁻¹² m², and/or
has an adhesive strength of at least 2 MPa, preferably at least 4 MPa, and/or
has an average layer thickness of at least 20 μm, preferably from 20 μm to 150 μm, particularly preferably from 30 μm to 100 μm.

The relative density can be determined, for example, via REM cross-section analysis. The average layer thickness can be determined, for example, via cross-section analysis. The permeability can be determined, for example, via a setup for measuring a gas volume flow through the sample as a function of a pressure difference through the sample and conversion into Darcy's permeability constant. The adhesive strength can be determined, for example, via tensile tests.

The at least one first sintered layer preferably has a lower permeability than the at least one second sintered layer.

The at least one first sintered layer preferably has a higher adhesive strength than the at least one second sintered layer.

The at least one first sintered layer preferably has a lower layer thickness than the at least one second sintered layer.

The at least one first sintered layer particularly preferably has a lower permeability, higher adhesive strength and a lower layer thickness than the at least one second sintered layer.

According to a further preferred embodiment of the coated substrate according to the invention, the coated substrate comprises at least one third sintered layer arranged on the at least one second sintered layer, the third sintered layer comprising or consisting of at least one refractory metal carbide, the at least one third sintered layer comprising no sintering additive, and the relative density of the at least one third sintered layer being at least 5%, preferably at least 10%, particularly preferably 10% to 30%, very particularly preferably 15% to 25%, particularly 18% to 22% lower than the relative density of the at least a second sintered layer. The at least one refractory metal carbide comprised in the at least one third sintered layer can be identical to the refractory metal carbide comprised in the at least one first sintered layer and/or to the refractory metal carbide comprised in the at least one second sintered layer. The at least one refractory metal carbide comprised in the at least one third sintered layer is preferably selected from the group consisting of titanium carbides, zirconium carbides, hafnium carbides, vanadium carbides, niobium carbides, tantalum carbides, chromium carbides, molybdenum carbides, tungsten carbides, and mixtures thereof.

Furthermore, it is preferred that the at least one third sintered layer comprises a layer sequence of several sintered layers, the relative density of the several sintered layers within the layer sequence decreasing as the distance from the at least one second sintered layer increases. The relative density can be determined, for example, via REM cross-section analysis.

Furthermore, it is preferred that the coated substrate according to the invention can be prepared or is prepared using the method according to the invention for preparing coated substrates

The present invention also relates to the use of the coated substrate according to the invention in semiconductor crystal growth, the coated substrate preferably being a coated crucible.

The coated substrate according to the invention can be used, for example, as a gallium evaporator or part of a gallium evaporator in a VPE-GaN reactor that can be used to grow gallium nitride semiconductor crystals, the layer system comprised in the coated substrate according to the invention then functioning as a coating for the gallium evaporator. In this case, the base material of the gallium evaporator can be protected particularly well from the corrosive gallium melt by the at least one first sintered layer due to the higher relative density, whereas the gallium evaporation rate and thus also the gallium nitride growth rate can be increased by the lower relative density and the higher porosity of the at least one second sintered layer of the layer system since there is a larger contact surface for the gallium melt.

The present invention also relates to the following aspects:

### Aspect 1

A method for preparing coated substrates, in which
a) a first aqueous suspension is prepared, the first aqueous suspension comprising or consisting of at least one refractory metal carbide, at least one sintering additive selected from the group consisting of silicon, zirconium boride, refractory metal silicides and mixtures thereof, and water.
b) a second aqueous suspension is prepared, which comprises at least one refractory metal carbide and water, the second aqueous suspension comprising
   at least one sintering additive selected from the group consisting of silicon, zirconium boride, refractory metal silicides and mixtures thereof, the percentage by weight of the at least one sintering additive in the second aqueous suspension, based on the total weight of the second aqueous suspension, being smaller than the percentage by weight of the at least a sintering additive in the first aqueous suspension, based on the total weight of the first aqueous suspension, or
   comprising no sintering additive,
c) at least one layer (2) of the first aqueous suspension is applied to a substrate (1), d) at least one layer (3) of the second aqueous suspension is applied to the at least one layer (2) of the first aqueous suspension applied to the substrate (1), and
e) the substrate (1) is subjected to a sintering process after step d).

### Aspect 2

The method according to the preceding aspect, characterized in that
the substrate comprises or consists of a material selected from the group consisting of graphite, preferably iso-graphite, carbon fiber reinforced carbon (CFC), C/SiC fiber composites, SiC/SiC fiber composites, carbidic ceramics, nitridic ceramics, oxidic ceramics, and mixtures thereof, and/or
the refractory metal silicides are selected from the group consisting of titanium silicides, zirconium silicides, hafnium silicides, vanadium silicides, niobium silicides, tantalum silicides, chromium silicides, molybdenum silicides, tungsten silicides, and mixtures thereof, and/or
the at least one refractory metal carbide is selected from the group consisting of titanium carbides, zirconium carbides, hafnium carbides, vanadium carbides, niobium carbides, tantalum carbides, chromium carbides, molybdenum carbides, tungsten carbides, and mixtures thereof.

### Aspect 3

The method according to any one of the preceding aspects, characterized in that
the at least one refractory metal carbide and the at least one sintering additive are each present in particulate form, wherein the mean particle size of the particles of the at least one sintering additive is less than 5 μm and/or smaller than the mean particle size of the particles of the at least one refractory metal carbide, and/or
the at least one refractory metal carbide is present as a powder mixture which comprises or consists of powders which differ in terms of the average particle size of the particles, preferably of the same refractory metal carbide.

### Aspect 4

The method according to any one of the preceding aspects, characterized in that the first aqueous suspension and/or the second aqueous suspension
comprises 60 to 90% by weight, preferably 70 to 85% by weight, of the at least one refractory metal carbide, based on the total weight of the respective aqueous suspension, and/or
comprises 0.1 to 20% by weight, preferably 0.5 to 10% by weight, of the at least one sintering additive, based on the total weight of the respective aqueous suspension.

### Aspect 5

The method according to any one of the preceding aspects, characterized in that the weight percentage of the at least one sintering additive in the second aqueous suspension, based on the total weight of the second aqueous suspension, is less than by 0.1% by weight to 20% by weight, preferably by 0.5% by weight to 10% by weight than the weight percentage of the at least one sintering additive in the first aqueous suspension, based on the total weight of the first aqueous suspension.

### Aspect 6

The method according to any one of the preceding aspects, characterized in that the preparation of the first aqueous suspension in step a) and/or the preparation of the second aqueous suspension in step b) is carried out by mixing the components of the suspension to be prepared with the aid of a dispersing device, wherein the mixing is carried out with the aid of the dispersing device, preferably using grinding media and/or over a period of at least 12 hours.

### Aspect 7

The method according to any one of the preceding aspects, characterized in that the application of the at least one layer (2) of the first aqueous suspension in step c) and/or the application of the at least one layer (3) of the second aqueous suspension in step d)
is carried out by means of dipping, brushing or spray application, and/or
is carried out with an average layer thickness of less than 150 μm, preferably from 20 μm to 100 μm, particularly preferably from 30 am to 80 μm.

### Aspect 8

The method according to any one of the preceding aspects, characterized in that at least one third aqueous suspension is additionally prepared, the third aqueous suspension comprising or consisting of at least one refractory metal carbide and water, wherein the at least one third aqueous suspension comprises no sintering additive, and between steps d) and e), at least one layer of the at least one third aqueous suspension is applied to the at least one applied layer (3) of the second aqueous suspension.

### Aspect 9

The method according to any one of the preceding aspects, characterized in that the sintering process in step e)
is carried out at a temperature of from 2100° C. to 2500° C., preferably from 2200° C. to 2400° C., and/or
is carried out with a holding time of 1 h to 15 h, preferably of 2 h to 10 h, and/or
is carried out at a pressure of 0.1 bar to 10 bar, preferably 0.7 bar to 5 bar, and/or
is carried out such that after a first time segment of the sintering process, the pressure is increased, preferably by 3 bar to 7 bar, and/or
is carried out under an argon atmosphere.

### Aspect 10

A coated substrate comprising a substrate (1), at least one first sintered layer (4) arranged on the substrate (1) and comprising or consisting of at least one refractory metal carbide and at least one sintering additive selected from the group consisting of silicon, zirconium boride, refractory metal silicides and mixtures thereof, and at least one second sintered layer (5) arranged on the at least one first sintered layer (4), the second sintered layer comprising or consisting of at least one refractory metal carbide and optionally at least one sintering additive selected from the group consisting of silicon, zirconium boride, refractory metal silicides and mixtures thereof, the at least one first sintered layer (4) with a relative density of at least 70%, and the relative density of the at least one second sintered layer (5) being at least 3% lower than the relative density of the at least one first sintered layer (4).

### Aspect 11

The coated substrate according to aspect 10, characterized in that the at least one first sintered layer (4)
has a relative density of more than 75%, preferably more than 80%, particularly preferably more than 90%, very particularly preferably more than 95%, and/or
has a permeability of less than 1 e⁻¹¹ m², preferably less than 1 e⁻¹³ m², and/or
has an adhesive strength of at least 2 MPa, preferably at least 4 MPa, and/or
has an average layer thickness of at least 20 μm, preferably from 20 μm to 150 μm, particularly preferably from 30 am to 100 μm.

### Aspect 12

The coated substrate according to aspect 10 or 11, characterized in that the at least one second sintered layer (5)
has a relative density which is at least 5%, preferably at least 10%, particularly preferably 10% to 30%, very particularly preferably 15% to 25%, particularly 18% to 22% lower than the relative density of the at least one first sintered layer, and/or
has a permeability of less than 1 e⁻¹¹ m², preferably less than 1 e⁻¹² m², and/or
has an adhesive strength of at least 2 MPa, preferably at least 4 MPa, and/or
has an average layer thickness of at least 20 μm, preferably from 20 μm to 150 μm, particularly preferably from 30 am to 100 μm.

### Aspect 13

The coated substrate according to any one of aspects 10 to 12, characterized in that the coated substrate comprises at least one third sintered layer arranged on the at least one second sintered layer (5) and comprising or consisting of at least one refractory metal carbide, wherein the at least one third sintered layer comprises no sintering additive, and wherein the relative density of the at least one third sintered layer is at least 5% lower than the relative density of the at least one second sintered layer (5),

wherein the at least one third sintered layer preferably comprises a layer sequence of a plurality of sintered layers, wherein the relative density of the plurality of sintered layers within the layer sequence decreases as the distance from the at least one second sintered layer (5) increases.

### Aspect 14

The coated substrate according to any one of aspects 10 to 13, characterized in that the coated substrate can be prepared or is prepared using a method according to any one of aspects 1 to 9.

### Aspect 15

A use of a coated substrate according to any one of aspects 10 to 14 in semiconductor crystal growth, the coated substrate preferably being a coated crucible.

The present invention is explained based on the following figures and examples in more detail without restricting the invention to the parameters specifically shown.

FIG. 1 shows part of an exemplary variant of the method according to the invention. In this example, a (closed) crucible, preferably a graphite crucible, for example, an iso-graphite crucible, is used as a substrate 1, the crucible to be used in semiconductor crystal growth. A growth atmosphere is present inside the crucible in this application. FIG. 1 now describes schematically, as step A, an application of a first layer 2 on the entire surface of the substrate 1 and, as step B, an application of a second layer 3 on the part of the first layer 2, which is applied on the inner side of the substrate 1. A specific layer architecture or a specific layer structure consisting of two layers is thus obtained. The first layer 2 is obtained by applying a layer of a first aqueous suspension consisting of tantalum carbide, water and a sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, refractory metal silicides, and mixtures thereof, preferably selected from the group consisting of silicon, zirconium boride, refractory metal silicides, and mixtures thereof. The second layer 3 is obtained by applying a layer of a second aqueous suspension consisting of tantalum carbide and water and therefore comprising no sintering additive. The application of the first layer 2 in step A and the application of the second layer 3 in step B can each be carried out by means of spray application. Only after the second layer 3 has been applied is the (coated) substrate sintered in step C, so that the first layer 2 and the second layer 3 are sintered together, the first sintered layer 4 being formed from the first layer 2 and the second sintered layer 5 being formed from the second layer 3. The layer architecture or the layer structure is compacted in a targeted manner during sintering.

The coated substrate thus obtained has a very advantageous layer structure consisting of two different sintered layers 5, 6. Due to the use of the sintering additive in the first layer 2, the sintered layer 4 has a high relative density, as a result of which the substrate is very well protected by the corrosive melt used in semiconductor crystal growth. The second sintered layer 5 has a lower relative density than the first sintered layer 4 due to the absence of sintering additive in the second layer 3. The layer structure obtained thus has a density gradient in which the degree of compaction or the relative density decreases with increasing distance from the substrate (that is, from the first sintered layer 4 to the second sintered layer 5). The higher porosity of the second sintered layer 5 resulting therefrom compared to the first sintered layer 4 leads to advantages when using the coated substrate in semiconductor crystal growth, since said higher porosity provides a larger contact surface for the melt used in crystal growth, whereby the evaporation rate and thus the growth rate can be increased.

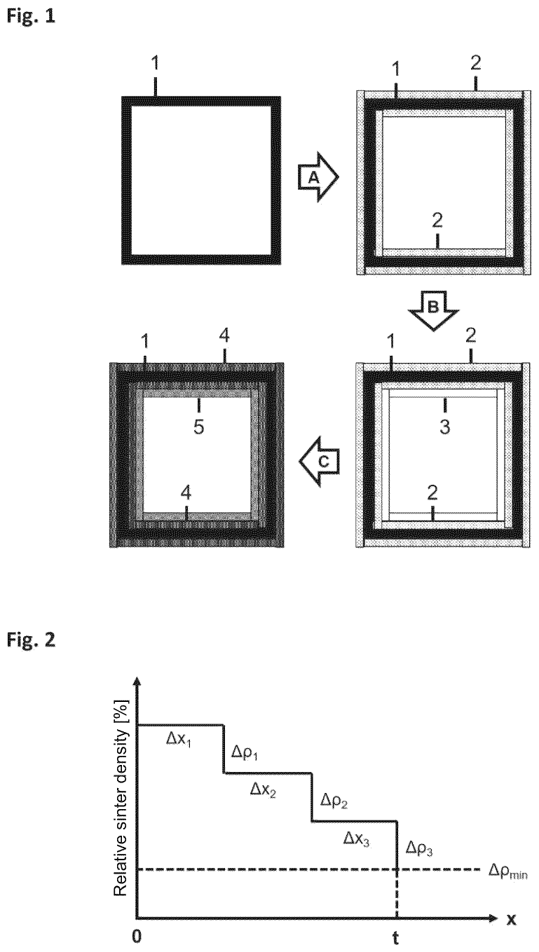

FIG. 2 graphically shows the density distribution within the layer system for an exemplary coated substrate according to the invention, the graph shown showing the relative sintered density as a function of the layer thickness (or the distance from the substrate surface). The exemplary coated substrate described here has a layer structure with three sintered layers of different relative densities. The point 0 on the x-axis represents the substrate surface, with t indicating the layer thickness of the entire coating with the first, second and third sintered layers. The Ax values indicate the distance between two layers of different density, so that Δx₁ corresponds to the thickness of the first sintered layer, Δx₂ to the thickness of the second sintered layer and Δx₃ to the thickness of the third sintered layer. The difference in the density of the adjacent sintered layers is quantified with Ap. The first sintered layer, that is, the sintered layer directly in contact with the substrate, has a relative density of at least 70%. In the graph shown in FIG. 2, it can now be seen that the relative density in the sintered layers of the layer system decreases with increasing distance from the substrate, that is, the second sintered layer has a (by at least 5%) lower relative density than the first sintered one layer and the third sintered layer has a (by at least 5%) relative density lower than the second sintered layer. This results in a density gradient within the layer system. In order to determine the graphically displayed values, an SEM image of a polished cross-section can be used to distinguish over which Ax there is a uniform density. A sintered density can then be calculated for Ax on the basis of the determined Ax and the mass of this area determined during coating. The difference in the density of the adjacent layers, with an extent of Ax, is quantified with Ap.

### EMBODIMENT EXAMPLE 1

First, a first aqueous suspension consisting of 80% by weight tantalum carbide, 1% by weight silicon as a sintering additive and 19% by weight water and a second aqueous suspension consisting of 80% by weight tantalum carbide and 20% by weight water were prepared. The second aqueous suspension therefore comprises no sintering additive. The mean powder particle size of the TaC particles is preferably in the range between 0.2 and 2 μm. To prepare the aqueous suspensions, the mixtures of the respective components are mixed with the aid of a dispersing device (rotational speeds up to 1 m/s) and, if necessary, using grinding media. The mixing process can take at least 12 hours.

A layer 2 of the first aqueous suspension is then applied to a substrate 1, preferably a graphite substrate, for example, an iso-graphite substrate. Application is carried out by means of spray application, a layer 2 of the first aqueous suspension being applied with an average layer thickness in the range from 20 to 80 μm. Alternatively, application can also be carried out, for example, by dipping or brushing.

A layer 3 of the second aqueous suspension is then applied to a section of the layer 2 of the first aqueous suspension applied to the substrate. Application here also is carried out by means of spray application, a layer 3 of the second aqueous suspension being applied with an average layer thickness in the range from 20 to 80 μm. Alternatively, application can also be carried out here, for example, by dipping or brushing.

After the two layers 2, 3 have been applied, the coated substrate is subjected to a sintering process under an argon atmosphere at a temperature of 2300° C., a holding time of 3 h and a pressure of 5 bar. Since the sintering of all applied layers is carried out in one sintering pass, all individually applied layers sinter together, which leads to a layer system with stable connections even under high thermal stresses. The first sintered layer 4 resulting from the layer 2 of the first aqueous suspension has a high relative density of over 70% due to the use of the sintering additive. The second sintered layer 5 resulting from the layer 3 of the second aqueous suspension has a lower relative density and thus a higher porosity than the first sintered layer 4, since a sintering additive is not present in the second aqueous suspension.

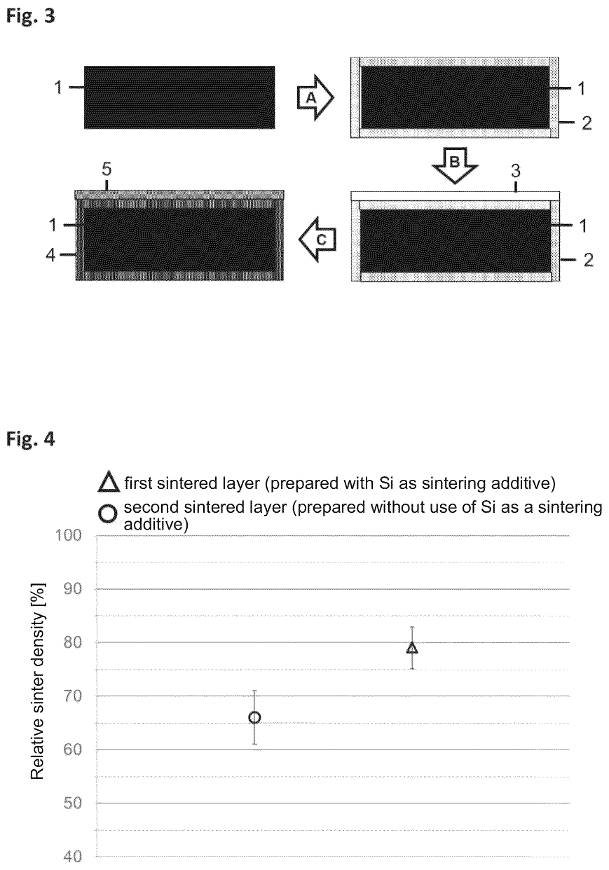

A schematic overview of the method steps carried out after the preparation of the aqueous suspensions is shown in FIG. 3.

In the sintered substrate prepared, the first sintered layer 4 has a permeability of less than 1 e⁻¹³ m², determined via a setup for measuring a gas volume flow through the sample as a function of a pressure difference through the sample and conversion into Darcy's permeability constant. The adhesive strength, determined by tensile tests, of the first sintered layer 4 is more than 4 MPa. In addition, the first sintered layer 4 has an average layer thickness of 25 μm to 30 μm, determined via cross-section analysis.

Based on the determination of the geometric density via the mass and volume of the compacted layers, a comparison of the degree of compaction of the first sintered layer 4 (resulting from the first aqueous suspension with 1% by weight sintering additive silicon) and the second sintered layer 5 (resulting from the second aqueous suspension without sintering additive) can additionally be made. The quantification of the increase in the degree of compaction is related to the relative density (ratio between geometric density and theoretical density of TaC with a value of 14.5 g/cm³). The result of the comparison is shown in FIG. 4, with the relative density of the first sintered layer 4 being represented by a triangle and the relative density of the second sintered layer 5 being represented by a circle. FIG. 4 shows that the first sintered layer 4 has a relative density of over 70% and also has a significantly higher relative density than the second sintered layer 5. This proves that the use of silicon as a sintering additive achieves a higher degree of compaction in the sintered layer.

### EMBODIMENT EXAMPLE 2

First, a first aqueous suspension consisting of 80% by weight tantalum carbide, 1% by weight of molybdenum silicide as a sintering additive (MoSi₂) and 19% by weight water and a second aqueous suspension consisting of 80% by weight tantalum carbide and 20% by weight water were prepared. The second aqueous suspension therefore comprises no sintering additive. The mean powder particle size of the TaC particles is preferably in the range between 0.2 and 2 μm. To prepare the aqueous suspensions, the mixtures of the respective components are mixed with the aid of a dispersing device (rotational speeds up to 1 m/s) and, if necessary, using grinding media. The mixing process can take at least 12 hours.

A layer 2 of the first aqueous suspension is then applied to a substrate 1, preferably a graphite substrate, for example, an iso-graphite substrate. Application is carried out by means of spray application, a layer 2 of the first aqueous suspension being applied with an average layer thickness in the range from 20 to 80 μm. Alternatively, application can also be carried out, for example, by dipping or brushing.

A layer 3 of the second aqueous suspension is then applied to a section of the layer 2 of the first aqueous suspension applied to the substrate. Application here also is carried out by means of spray application, a layer 3 of the second aqueous suspension being applied with an average layer thickness in the range from 20 to 80 μm. Alternatively, application can also be carried out here, for example, by dipping or brushing.

After the two layers 2, 3 have been applied, the coated substrate is subjected to a sintering process under an argon atmosphere at a temperature of 2300° C., a holding time of 3 h and a pressure of 5 bar. Since the sintering of all applied layers is carried out in one sintering pass, all individually applied layers sinter together, which leads to a layer system with stable connections even under high thermal stresses. The first sintered layer 4 resulting from the layer 2 of the first aqueous suspension has a high relative density of at least 70% due to the use of the sintering additive. The second sintered layer 5 resulting from the layer 3 of the second aqueous suspension has a lower relative density and thus a higher porosity than the first sintered layer 4, since a sintering additive is not present in the second aqueous suspension.

A schematic overview of the method steps carried out after the preparation of the aqueous suspensions is shown in FIG. 3.

In the coated substrate prepared, the first sintered layer 4 has a permeability of less than 1 e⁻¹³ m², determined via a setup for measuring a gas volume flow through the sample as a function of a pressure difference through the sample and conversion into Darcy's permeability constant. The adhesive strength, determined by tensile tests, of the first sintered layer 4 is more than 4 MPa. In addition, the first sintered layer 4 has an average layer thickness of 45 μm to 50 μm, determined via cross-section analysis.

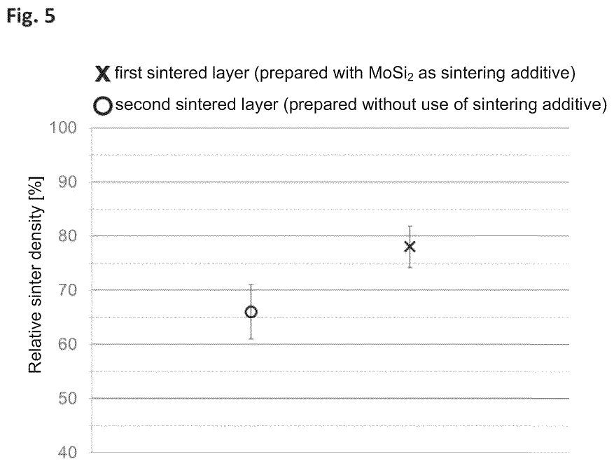

Based on the determination of the geometric density via the mass and volume of the compacted layers, a comparison of the degree of compaction of the first sintered layer 4 (resulting from the first aqueous suspension with 1% by weight sintering additive MoSi₂) and the second sintered layer 5 (resulting from the second aqueous suspension without sintering additive) can then be made. The quantification of the increase in the degree of compaction is related to the relative density (ratio between geometric density and theoretical density of TaC with a value of 14.5 g/cm³). The result of the comparison is shown in FIG. 5, with the relative density of the first sintered layer 4 being represented by a cross and the relative density of the second sintered layer 5 being represented by a circle. It is apparent from FIG. 5 that the relative density of the first sintered layer 4 is more than 70%.

In addition, the first sintered layer has a significantly higher relative density than the second sintered layer 5. This proves that the use of MoSi₂ as a sinter additive achieves a higher degree of compaction in the sintered layer.

1-15. (canceled)

16. A method for preparing coated substrates, in which
a) a first aqueous suspension is prepared, which comprises at least one refractory metal carbide, at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, and a refractory metal silicide, and water,
b) a second aqueous suspension is prepared, which comprises at least one refractory metal carbide and water,
the second aqueous suspension comprising
at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, and refractory metal silicides,
wherein the percentage by weight of the at least one sintering additive in the second aqueous suspension, based on the total weight of the second aqueous suspension, is less than the percentage by weight of the at least one sintering additive in the first aqueous suspension, based on the total weight of the first aqueous suspension, or
the second aqueous suspension comprising no sintering additive,
c) at least one layer of the first aqueous suspension is applied to a substrate,
d) at least one layer of the second aqueous suspension is applied to the at least one layer of the first aqueous suspension applied to the substrate, and
e) the substrate is subjected to a sintering process after step d).

17. The method according to claim 16, wherein
the substrate comprises a material selected from the group consisting of graphite, a carbon fiber reinforced carbon (CFC), a C/SiC fiber composite, a SiC/SiC fiber composite, a carbidic ceramic, a nitridic ceramic, an oxidic ceramic, and mixtures thereof, and/or
the refractory metal silicides are selected from the group consisting of titanium silicides, zirconium silicides, hafnium silicides, vanadium silicides, niobium silicides, tantalum silicides, chromium silicides, molybdenum silicides, tungsten silicides, and mixtures thereof, and/or
the at least one refractory metal carbide is selected from the group consisting of titanium carbides, zirconium carbides, hafnium carbides, vanadium carbides, niobium carbides, tantalum carbides, chromium carbides, molybdenum carbides, and tungsten carbides.

18. The method according to claim 16, wherein
the at least one refractory metal carbide and the at least one sintering additive are each present in particulate form, wherein the mean particle size of the particles of the at least one sintering additive is less than 5 μm and/or smaller than the mean particle size of the particles of the at least one refractory metal carbide, and/or
the at least one refractory metal carbide is present as a powder mixture which comprises powders which differ in terms of the average particle size of the particles.

19. The method according to claim 16, wherein the first aqueous suspension and/or the second aqueous suspension
comprises 60 to 90% by weight of the at least one refractory metal carbide, based on the total weight of the respective aqueous suspension, and/or
comprises 0.1 to 20% by weight of the at least one sintering additive, based on the total weight of the respective aqueous suspension.

20. The method according to a claim 16, wherein the weight percentage of the at least one sintering additive in the second aqueous suspension, based on the total weight of the second aqueous suspension, is less than by 0.1% by weight to 20% by weight than the weight percentage of the at least one sintering additive in the first aqueous suspension, based on the total weight of the first aqueous suspension.

21. The method according to claim 16, wherein the preparation of the first aqueous suspension in step a) and/or the preparation of the second aqueous suspension in step b) is/are carried out by mixing the components of the suspension to be prepared with the aid of a dispersing device, wherein the mixing is carried out with the aid of the dispersing device.

22. The method according to claim 16, wherein the application of the at least one layer of the first aqueous suspension in step c) and/or the application of the at least one layer of the second aqueous suspension in step d)
is carried out by means of dipping, brushing, or spray application, and/or
is carried out with an average layer thickness of less than 150 μm.

23. The method according to claim 16, wherein
at least one third aqueous suspension is additionally prepared, the third aqueous suspension comprising at least one refractory metal carbide and water, wherein the at least one third aqueous suspension comprises no sintering additive, and
between steps d) and e), at least one layer of the at least one third aqueous suspension is applied to the at least one applied layer of the second aqueous suspension.

24. The method according to claim 16, wherein the sintering process in step e)
is carried out at a temperature of from 2100° C. to 2500° C., and/or
is carried out with a holding time of 1 h to 15 h, and/or
is carried out at a pressure of 0.1 bar to 10 bar, and/or
is carried out such that after a first time segment of the sintering process, the pressure is increased, and/or
is carried out under an argon atmosphere.

25. A coated substrate, comprising a substrate, at least one first sintered layer arranged on the substrate and comprising at least one refractory metal carbide and at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, and a refractory metal silicide, and at least one second sintered layer arranged on the at least one first sintered layer and comprising at least one refractory metal carbide and optionally at least one sintering additive selected from the group consisting of silicon, hafnium, zirconium, vanadium, tantalum pentoxide, boron carbide, silicon carbide, tungsten carbide, vanadium carbide, molybdenum carbide, boron nitride, tantalum nitride, zirconium nitride, niobium nitride, tantalum diboride, tungsten diboride, zirconium boride, and a refractory metal silicide, wherein the at least one first sintered layer with a relative density of at least 70%, and the relative density of the at least one second sintered layer is at least 3% lower than the relative density of the at least one first sintered layer.

26. The coated substrate according to claim 25, wherein the at least one first sintered layer
has a relative density of more than 75%, and/or
has a permeability of less than 1 e¹¹ m², and/or
has an adhesive strength of at least 2 MPa, and/or
has an average layer thickness of at least 20 μm.

27. The coated substrate according to claim 25, wherein the at least one second sintered layer
has a relative density which is at least 5% lower than the relative density of the at least one first sintered layer, and/or
has a permeability of less than 1 e¹¹ m², and/or
has an adhesive strength of at least 2 MPa, and/or
has an average layer thickness of at least 20 μm.

28. The coated substrate according to claim 25, wherein the coated substrate comprises at least one third sintered layer arranged on the at least one second sintered layer and comprising at least one refractory metal carbide, wherein the at least one third sintered layer comprises no sintering additive, and wherein the relative density of the at least one third sintered layer is at least 5% lower than the relative density of the at least one second sintered layer.

29. The coated substrate according to claim 28, wherein the at least one third sintered layer comprises a layer sequence of a plurality of sintered layers, wherein the relative density of the plurality of sintered layers within the layer sequence decreases as the distance from the at least one second sintered layer increases.

30. A coated substrate prepared according to claim 16.

31. A method of growing a semiconductor crystal comprising growing a semiconductor crystal in a coated substrate according to claim 25, wherein the coated substrate is configured to be a coated crucible.
